(19) United States
(12) Patent Application Publication
(10) Pub. No.: US 2026/0075807 A1
(43) Pub. Date: Mar. 12, 2026

(54) SEMICONDUCTOR DEVICE AND METHOD OF MANUFACTURING THE SAME

(71) Applicant: NANYA TECHNOLOGY CORPORATION, New Taipei City (TW)

(72) Inventor: Feng Wen HSU, New Taipei City (TW)

(21) Appl. No.: 18/830,592

(22) Filed: Sep. 11, 2024

(51) Int. Cl. H10B 12/00

(52) U.S. Cl. CPC H10B 12/34; H10B 12/053

(57) ABSTRACT

A semiconductor device including a substrate including an active area and an isolation structure surrounding the active area, an active gate structure disposed in the active area, a passing gate structure disposed in the isolation structure, and a storage node disposed between the passing gate structure and the active gate structure. The isolation structure is a bi-layer structure, and an average dielectric constant of the isolation structure is less than 3.9. A method of forming a semiconductor device is also disclosed.

### BACKGROUND

### FIELD OF INVENTION

The present disclosure relates to a semiconductor device and a method of manufacturing the same.

### Description of Related Art

Smaller and lighter electronics devices have driven semiconductor devices shirked with a high degree of integration. The highly compact semiconductor devices result in limited space for element configuration. For example, a buried gate structure of a semiconductor device including a gate dielectric layer and a gate electrode in a trench introduced. The gate dielectric layer covers the surface of the trench and the gate electrode partially fills the trench on the gate dielectric layer. The buried gate structure may be adjacent to (or on the same level as) impurity regions or junction regions in an active region of the semiconductor device.

### SUMMARY

An aspect of the disclosure provides a semiconductor device including a substrate including an active area and an isolation structure surrounding the active area, an active gate structure disposed in the active area, a passing gate structure disposed in the isolation structure, and a storage node disposed between the passing gate structure and the active gate structure. The isolation structure is a bi-layer structure, and an average dielectric constant of the isolation structure is less than 3.9.

In some embodiments, the isolation structure includes a lining layer disposed between the passing gate structure and the substrate, and a dielectric material disposed between the passing gate structure and the lining layer, wherein a dielectric constant of the dielectric material is less than a dielectric constant of lining layer.

In some embodiments, the dielectric constant of the lining layer is about 3.9, and the dielectric constant of the dielectric material is less than 3.9.

In some embodiments, the dielectric material includes a plurality of air voids.

In some embodiments, top surfaces of the lining layer, the dielectric material, and the active area are coplanar.

In some embodiments, the storage node includes poly-silicon or metal.

In some embodiments, a bottom surface of the storage node is below a top surface of the active area.

In some embodiments, the passing gate structure is deeper and wider than the active gate structure.

In some embodiments, the passing gate structure includes a gate electrode, a capping layer on the gate electrode, and a gate dielectric surrounding the gate electrode and the capping layer.

Another aspect of the disclosure provides a method of forming a semiconductor device. The method includes forming an isolation trench in a substrate, wherein an active area is defined by the isolation trench in the substrate; forming an isolation structure in the isolation trench, wherein the isolation structure is a bi-layer structure, and an average dielectric constant of the isolation structure is less than 3.9; forming a passing gate structure in the isolation structure and forming an active gate structure the active area; and forming a storage node between the passing gate structure and the active gate structure.

In some embodiments, the passing gate structure and the active gate structure are formed simultaneously.

In some embodiments, forming an isolation structure in the isolation trench includes forming a lining layer on a sidewall of the isolation trench; and forming a dielectric material filling the isolation trench, wherein a dielectric constant of the dielectric material is less than a dielectric constant of lining layer.

In some embodiments, the dielectric constant of the lining layer is about 3.9, and the dielectric constant of the dielectric material is less than 3.9.

In some embodiments, forming a dielectric material filling the isolation trench includes forming a plurality of air voids in the dielectric material.

In some embodiments, the method further includes forming an insulating layer on the substrate, wherein forming a storage node between the passing gate structure and the active gate structure includes forming an opening exposing the active area, and depositing a conductive material in the opening.

In some embodiments, the conductive material includes poly-silicon or metal.

In some embodiments, the storage node is embedded in the active area, and a bottom surface of the storage node is lower than a top surface of the active area.

In some embodiments, forming a passing gate structure in the isolation structure and forming an active gate structure the active area includes forming a plurality of word line trenches in the isolation structure and the active area; depositing a gate dielectric layer on sidewalls of the word line trenches; forming a plurality of gate electrodes in the word line trenches; and forming a plurality of capping layers on the gate electrodes, respectively.

In some embodiments, a plurality of passing sections of the word line trenches in the isolation structure are deeper than a plurality of active sections of the word line trenches in the active area.

In some embodiments, a plurality of passing sections of the word line trenches in the isolation structure are wider than a plurality of active sections of the word line trenches in the active area.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is an arrangement diagram of a semiconductor device according to some embodiments of the present disclosure.

FIG. 2 to FIG. 8 are cross-sectional views illustrating different steps of a method of forming a semiconductor device in accordance with some embodiments of the present disclosure, respectively.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

In related art of the semiconductor device with the buried gate structure, the gate dielectric layer (or a sidewall dielectric) of the buried gate structure may inevitably be consumed and the effective electric field near the gate electrode may become higher. This causes gate induced drain leakage (GIDL) to occur. GIDL discharges the stored charges, thereby deteriorating the operational reliability of the semiconductor device. The present disclosure provides a semiconductor device with an enhanced buried gate structure as passing gate, to improve GIDL.

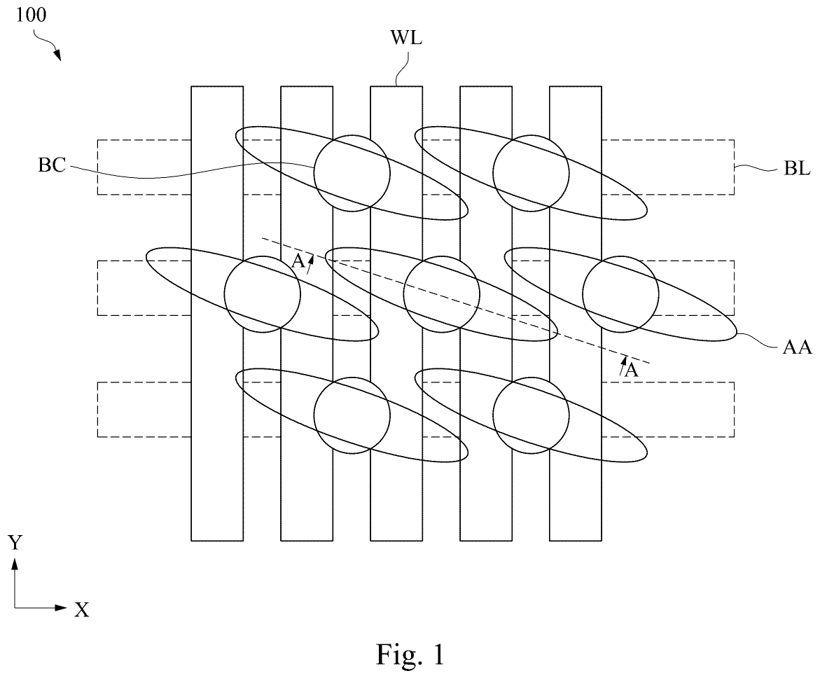

Reference is made to FIG. 1. FIG. 1 is an arrangement diagram of a semiconductor device according to some embodiments of the present disclosure. The semiconductor device 100 may include a plurality of active areas AA. In some embodiments, each of the active area AA has a short axis and a long axis and is in a shape of ellipse in a top view. In some embodiments, the long axis of the active area AA may extend in a diagonal axis with respect to an X axis.

A plurality of word lines WL are configured across the active areas AA and extend along a Y axis. The word lines WL are in parallel to each other. Additionally, the word lines WL may be spaced apart from each other at substantially equal intervals.

A plurality of bit lines BL are arranged above the word lines WL and may extend along the X axis. Similarly, the lines BL are in parallel to each other. In addition, the bit lines BL can be connected to the corresponding active areas AA through bit line contacts BC. In some embodiments, one active area AA may be electrically connected to one bit line contact BC.

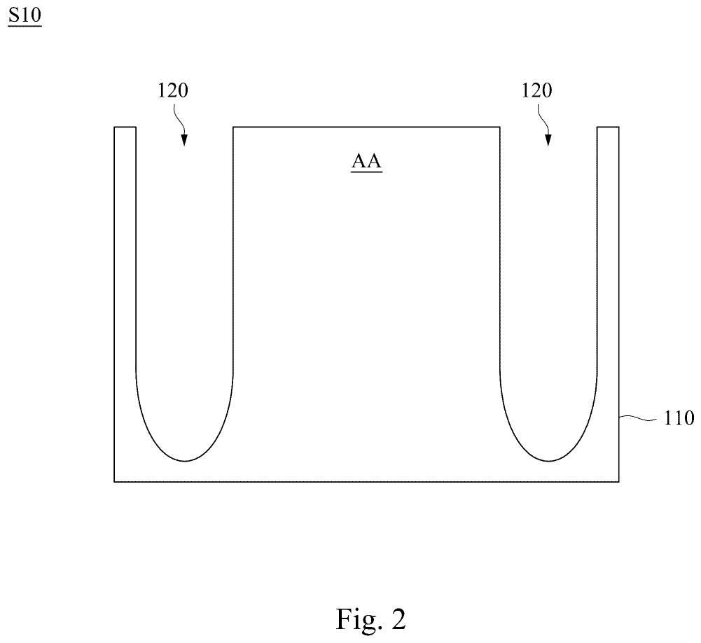

Reference is made to FIG. 2 to FIG. 8. FIG. 2 to FIG. 8 are cross-sectional views illustrating different steps of a method of forming a semiconductor device in accordance with some embodiments of the present disclosure, respectively. The cross-section views of FIG. 2 to FIG. 8 are based on a reference cross-sectional view taken along line A-A shown in FIG. 1.

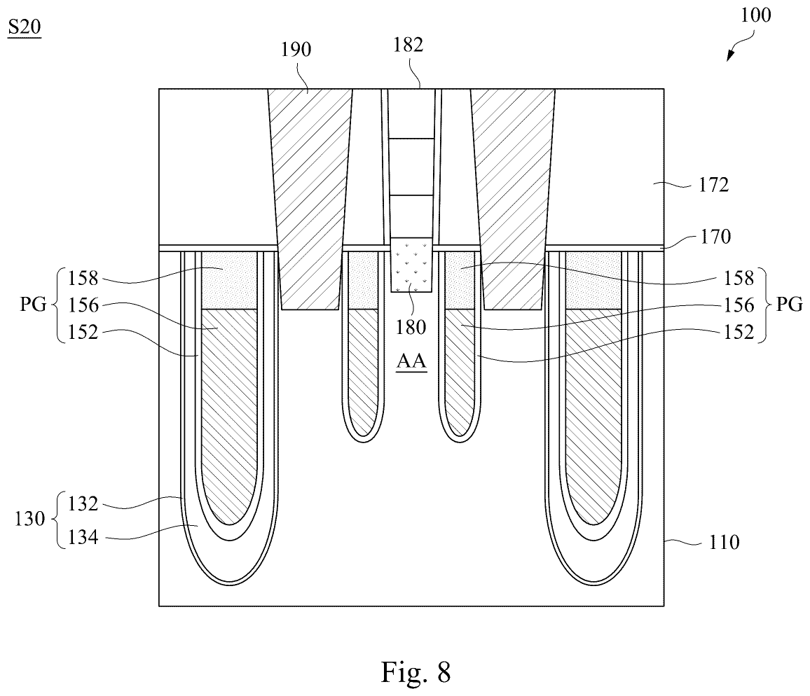

It should be noted that when the following figures, such as FIGS. 2 to 8, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor device (for example, a semiconductor device 100 in FIG. 8) to completely form the semiconductor device. Therefore, the present disclosure may briefly illustrate some of these additional operations or steps.

Reference is made to FIG. 2. The method of forming the semiconductor device begins from step S10 including forming an isolation trench 120 in a substrate 110. The active areas AA are surrounded by the isolation trench 120. In some embodiments, after a pad layer (not shown) is formed on the substrate 110, the pad layer and the substrate 110 are etched to define the isolation trench 120.

In some embodiments, the substrate 110 may include a semiconductor substrate. In some embodiments, the substrate 110 may include, for example, bulk silicon (Si), monocrystalline silicon, polysilicon, amorphous silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some other embodiments, the substrate 110 may include a layered semiconductor such as silicon/silicon germanium, silicon-on-insulator, or silicon germanium-on-insulator.

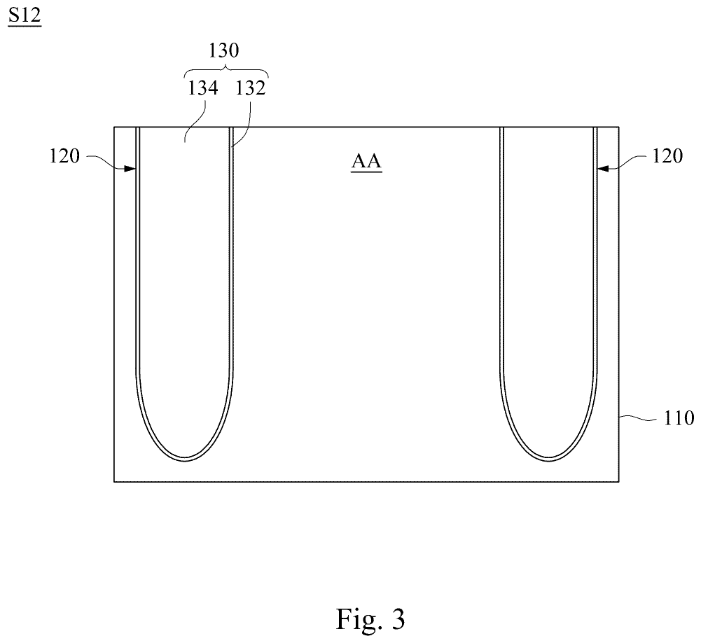

Reference is made to FIG. 3. The method of forming the semiconductor device goes to step S12 including forming an isolation structure 130 in the isolation trench. The active areas AA are defined by the isolation structure 130. In some embodiments, the isolation structure 130 is a shallow trench isolation (STI) structure. The isolation structure 130 is formed by more than one deposition processes.

In some embodiments, a lining layer 132 is formed on the sidewall of the isolation trench 120. In some embodiments, the lining layer 132 is conformally formed on the sidewall of the isolation trench 120 with a uniform thickness. In some embodiments, the lining layer 132 may be formed through thermal oxidation of the substrate 110, chemical oxidation of the substrate 110, or a deposition step.

After the lining layer 132 is formed, a deposition process is performed to deposit a dielectric material 134 filling the isolation trench 120. In some embodiments, a planarization process is performed such that the top surfaces of the lining layer 132, the dielectric material 134, and the substrate 110 are coplanar, and the isolation structure 130 including the lining layer 132 and the dielectric material 134 are formed in the isolation trench 120.

The dielectric constant (k) of the dielectric material 134 is different from the dielectric constant of the lining layer 132. In some embodiments, the dielectric constant of the dielectric material 134 is less than the dielectric constant of the lining layer 132.

In some embodiments, the material of the lining layer 132 includes silicon oxide, silicon nitride, silicon oxynitride, or combinations thereof. In some embodiments, the material of the lining layer 132 is oxide such as silicon oxide (SiO₂), and the dielectric constant of the lining layer 132 is about 3.9.

In some embodiments, the material of the dielectric material 134 is a dielectric material having a dielectric constant less than 3.9. In some embodiments, one approach to reduce the dielectric constant of the dielectric material 134 is to introduce carbon (C) or fluorine (F) atoms. For example, in SiO₂ (k=3.9), the introduction of C atoms to form hydrogenated carbon-doped silicon oxide (SiCOH) (k is between 2.7 and 3.3) and the introduction of F atoms to form fluorosilicate glass (FSG) (k is between 3.5 and 3.9) reduces its dielectric constant.

In some embodiments, the material of the dielectric material 134 is a low-k material, for example, nanopore carbon doped oxide (CDO), black diamond (BD), a benzocyclobutene (BCB) based polymer, an aromatic (hydrocarbon) thermosetting polymer (ATP), hydrogen silsesquioxane (HSQ), methyl silsesquioxane (MSQ), poly-arylene ethers (PAE), diamond-like carbon (DLC) doped with nitrogen, or combinations thereof.

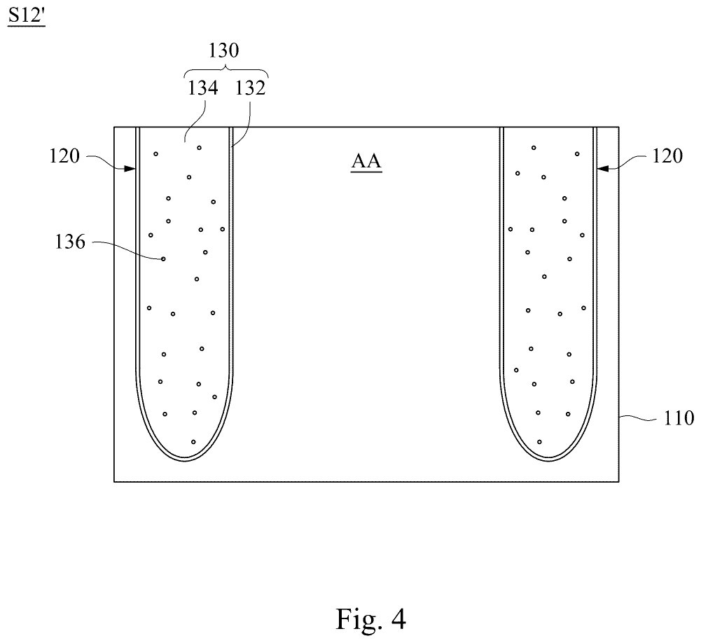

In some embodiments, as shown the step S12′ in FIG. 4, the deposition process of forming the dielectric material 134 includes forming a plurality of air voids 136 in the dielectric material 134. The dielectric constant of the air voids 136 is about 1. Therefore, the dielectric constant of dielectric material 134 having the air voids 136 is reduced.

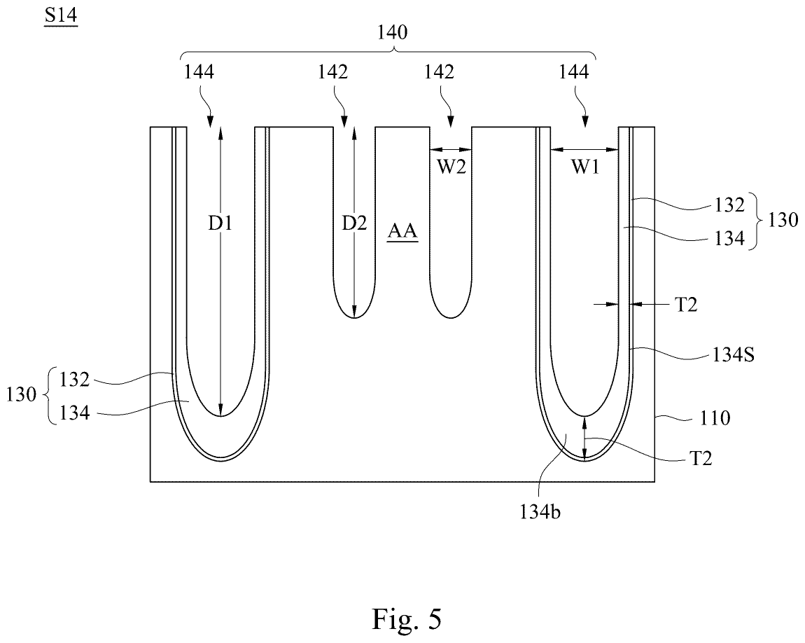

Reference is made to FIG. 5. The method of forming the semiconductor device goes to step S14, followed after step S12 (or step S12′). Step S14 includes forming a plurality of word line trenches 140 in the substrate 110. In some embodiment, each of the word line trenches 140 includes active sections 142 passing through the active areas AA and passing sections 144 passing through the isolation structure 130. The active sections 142 passing through the active areas AA and the passing sections 144 passing through the isolation structure 130 are formed simultaneously in the same etching process. In some embodiments, the profile of the active sections 142 is different from the profile of the passing sections 144 because the material of the active areas AA is different from material of the isolation structure 130 thereby leading to etching selectivity between the active areas AA and the isolation structure 130.

In some embodiments, the depth D1 of the passing sections 144 is deeper than the depth D2 of the active sections 142. That is, the bottom surface of the passing sections 144 is lower than the bottom surface of the active sections 142. In some embodiments, the width W1 of the passing sections 144 is wider than the width W2 of the active sections 142.

In some embodiments, the etching process of forming the word line trenches 140 stops at the dielectric material 134. Portions of the dielectric material 134 are remained after the word line trenches 140 are formed. The thickness T1 of the bottom portion 134b of the remained dielectric material 134 is thicker than the thickness T2 of the sidewall portion 134s of the remained dielectric material 134. The lining layer 132 having the dielectric constant higher than the dielectric material 134 surrounds the dielectric material 134 and is between the dielectric material 134 and the substrate 110.

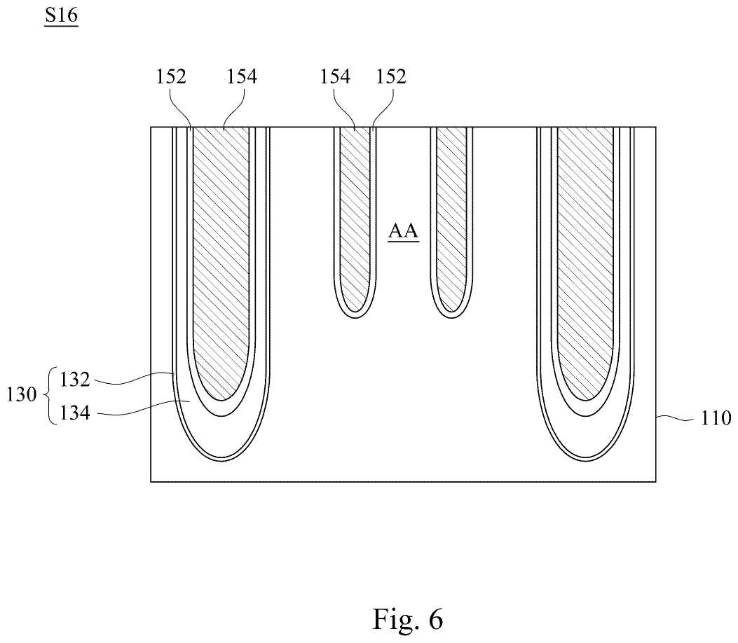

Reference is made to FIG. 6. The method of forming the semiconductor device goes to step S16 including forming a gate dielectric layer 152 on the sidewall of the word line trenches 140 (see FIG. 5) and depositing a conductive material 154 in the word line trenches 140. In some embodiments, a pre-cleaning process is performed prior to forming the gate dielectric layer 152. The gate dielectric layer 152 can be oxide such as a silicon oxide layer. In some embodiments, the dielectric constant of the gate dielectric layer 152 is same as the dielectric constant of the lining layer 132, and the gate dielectric layer 152 is denser than the lining layer 132.

In some other embodiments, the gate dielectric layer may include a high-k dielectric material, such as hafnium oxide, lanthanum oxide, aluminum oxide, or combinations thereof. The dielectric constant of the high-k dielectric material is higher than about 3.9, and may be higher than about 7, and sometimes as high as about 21 or higher.

After the gate dielectric layer 152 is formed on the sidewall of the word line trenches 140, the conductive material 154 is deposited filling the word line trenches 140. A planarization process is then performed such that the top surfaces of the lining layer 132, the dielectric material 134, the gate dielectric layer 152, the conductive material 154, and the substrate 110 are coplanar. In some embodiments, the conductive material 154 may include a single layer of metal, metal composite or layers of conductive materials. In some embodiments, the conductive material 154 may include a metal-based material. For example, the conductive material 154 may include titanium (Ti), titanium nitride (TiN), tantalum (Ta), tantalum nitride (TaN), tungsten (W), tungsten nitride (WN), a stack thereof or a combination thereof.

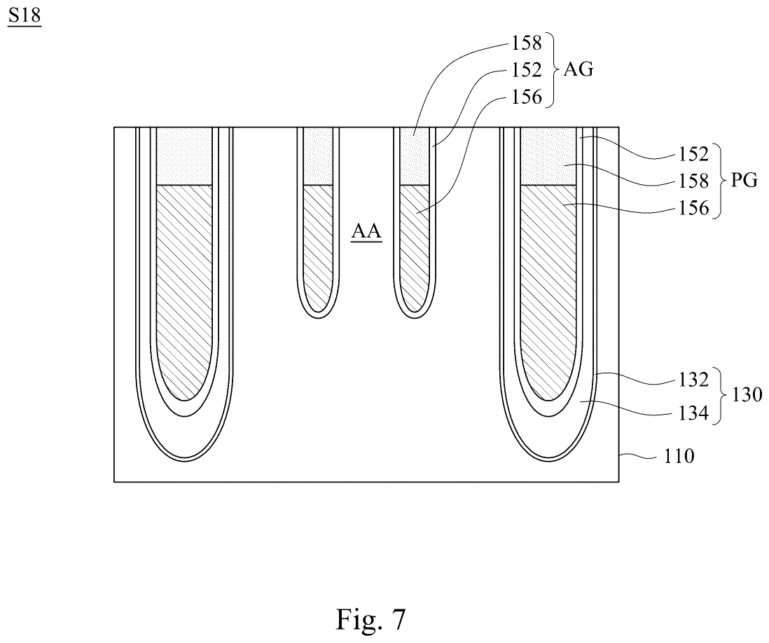

Reference is made to FIG. 7. The method of forming the semiconductor device goes to step S18. As shown in step S18, an etch back process is performed to remove portions of the conductive material 154 (as shown in FIG. 6) in the word line trenches 140 (see FIG. 5) thereby recessing the conductive material 154. Portions of the conductive material 154 are remained in the bottom of the word line trenches 140, and the remaining portions of the conductive material 154 can be regarded as gate electrodes 156 in the word line trenches 140. In some embodiments, the etch back process is a selective etching process which has a greater etching to the conductive material 154 than the gate dielectric layer 152, thus the gate dielectric layer 152 is remained on the sidewalls of the word line trenches 140 after the etch back process is performed. A cleaning process is performed to remove residues of the conductive material 154. The cleaning process can be a wet cleaning process, including using dilute HF as an etchant.

Step S18 further includes forming a plurality of capping layers 158 on the gate electrodes 156, respectively. The formation of the capping layers 158 includes depositing a nitride layer filling the word line trenches 140 and performing a planarization process to remove the exceeded portions of the nitride layer. The top surfaces of the lining layer 132, the dielectric material 134, the gate dielectric layer 152, the capping layers 158, and the substrate 110 are coplanar.

In some embodiments, the gate electrodes 156, the gate dielectric layer 152, and the capping layers 158 in the active area AA can be regarded as active gate structures AG, and the gate electrodes 156, the gate dielectric layer 152, and the capping layers 158 in the isolation structure 130 can be regarded as passing gate structures PG. In some embodiments, the passing gate structures PG are wider and deeper than the active gate structures AG.

Reference is made to FIG. 8. The method of forming the semiconductor device goes to step S20. An etch stop layer 170 and an insulating layer 172 are formed on the top surface of the substrate 110 by, for example, ALD, CVD, PVD, remote plasma CVD (RPCVD), plasma enhanced CVD (PECVD), coating, etc. The etch stop layer 170 and the insulating layer 172 are made of different compositions to provide better etching selectively. A plurality of bit line contacts 180 are formed in the etch stop layer 170 and the insulating layer 172, each of the bit line contacts 180 is disposed between adjacent two active gate structures AG. The bit line contact 180 is embedded in the active area AA. The material of the bit line contacts 180 includes conductive material such as poly-silicon, titanium (Ti), titanium nitride (TiN), tantalum (Ta), tantalum nitride (TaN), tungsten (W), or tungsten nitride (WN). Then, a plurality of bit line structure 182 are formed and electrically connected with the bit line contact 180. In some other embodiments, the bit line contact 180 and the bit line structure 182 can be both buried in the active area AA.

A plurality of storage nodes 190 are formed in the active area AA and are disposed between the bit line structures 182, respectively. The formation of the storage nodes 190 includes forming openings penetrates the etch stop layer 170 and the insulating layer 172, and the openings expose the active area AA. Then a conductive material such as poly-silicon or metal is deposited in the openings to form the storage nodes 190.

The storage nodes 190 connect the active area AA to a plurality of memory components (not shown), respectively. In some embodiments, the storage nodes 190 connect the active area AA to a plurality of capacitors. The material of the storage nodes 190 can be poly-silicon or metal. In some embodiments, the storage nodes 190 are also embedded in the active area AA such that the bottom surface of the storage nodes 190 are lower than the top surface of the active area AA.

Because both the storage nodes 190 and the gate electrodes 156 are made of conductive material, capacitances between passing gate structures PG and the storage nodes 190 are observed. The unpreventable capacitances between passing gate structures PG and the storage nodes 190 may lead to gate induced drain leakage (GIDL).

In the embodiments of the semiconductor device 100, the isolation structure 130 in which the passing gate structures PG are buried is a bi-layer structure and includes the lining layer 132 and the dielectric material 134. The dielectric constant of the lining layer 132 is about 3.9, and the dielectric constant of the dielectric material 134 is less than 3.9. Therefore, the average dielectric constant of the isolation structure 130 is also less than 3.9. The isolation structure 130 including the lining layer 132 and the dielectric material 134 is directly interposed between the passing gate structures PG and the storage nodes 190, and the dielectric constant of the isolation structure 130 is less than 3.9. Therefore, the capacitances between passing gate structures PG and the storage nodes 190 can be reduced, comparing to the conventional isolation structure using only silicon oxide, and the GIDL can be improved accordingly.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A semiconductor device comprising:
a substrate comprising an active area and an isolation structure surrounding the active area, wherein the isolation structure is a bi-layer structure, and an average dielectric constant of the isolation structure is less than 3.9;
an active gate structure disposed in the active area;
a passing gate structure disposed in the isolation structure; and
a storage node disposed between the passing gate structure and the active gate structure.

2. The semiconductor device of claim 1, wherein the isolation structure comprises:
a lining layer disposed between the passing gate structure and the substrate; and
a dielectric material disposed between the passing gate structure and the lining layer, wherein a dielectric constant of the dielectric material is less than a dielectric constant of lining layer.

3. The semiconductor device of claim 2, wherein the dielectric constant of the lining layer is about 3.9, and the dielectric constant of the dielectric material is less than 3.9.

4. The semiconductor device of claim 2, wherein the dielectric material comprises a plurality of air voids.

5. The semiconductor device of claim 2, wherein top surfaces of the lining layer, the dielectric material, and the active area are coplanar.

6. The semiconductor device of claim 1, wherein the storage node comprises poly-silicon or metal.

7. The semiconductor device of claim 1, wherein a bottom surface of the storage node is below a top surface of the active area.

8. The semiconductor device of claim 1, wherein the passing gate structure is deeper and wider than the active gate structure.

9. The semiconductor device of claim 1, wherein the passing gate structure comprises a gate electrode, a capping layer on the gate electrode, and a gate dielectric surrounding the gate electrode and the capping layer.

10. A method of forming a semiconductor device, the method comprising:
forming an isolation trench in a substrate, wherein an active area is defined by the isolation trench in the substrate;
forming an isolation structure in the isolation trench, wherein the isolation structure is a bi-layer structure, and an average dielectric constant of the isolation structure is less than 3.9;
forming a passing gate structure in the isolation structure and forming an active gate structure the active area; and
forming a storage node between the passing gate structure and the active gate structure.

11. The method of claim 10, wherein the passing gate structure and the active gate structure are formed simultaneously.

12. The method of claim 10, wherein forming an isolation structure in the isolation trench comprises:
forming a lining layer on a sidewall of the isolation trench; and
forming a dielectric material filling the isolation trench, wherein a dielectric constant of the dielectric material is less than a dielectric constant of lining layer.

13. The method of claim 12, wherein the dielectric constant of the lining layer is about 3.9, and the dielectric constant of the dielectric material is less than 3.9.

14. The method of claim 12, wherein forming a dielectric material filling the isolation trench comprises forming a plurality of air voids in the dielectric material.

15. The method of claim 10, further comprising forming an insulating layer on the substrate, wherein forming a storage node between the passing gate structure and the active gate structure comprises forming an opening exposing the active area, and depositing a conductive material in the opening.

16. The method of claim 15, wherein the conductive material comprises poly-silicon or metal.

17. The method of claim 10, wherein the storage node is embedded in the active area, and a bottom surface of the storage node is lower than a top surface of the active area.

18. The method of claim 10, wherein forming a passing gate structure in the isolation structure and forming an active gate structure the active area comprises:
forming a plurality of word line trenches in the isolation structure and the active area;
depositing a gate dielectric layer on sidewalls of the word line trenches;
forming a plurality of gate electrodes in the word line trenches; and
forming a plurality of capping layers on the gate electrodes, respectively.

19. The method of claim 18, wherein a plurality of passing sections of the word line trenches in the isolation structure are deeper than a plurality of active sections of the word line trenches in the active area.

20. The method of claim 18, wherein a plurality of passing sections of the word line trenches in the isolation structure are wider than a plurality of active sections of the word line trenches in the active area.
